(19) United States
(12) Patent Application Publication
(10) Pub. No.: US 2025/0210371 A1
(43) Pub. Date: Jun. 26, 2025

(54) SUBSTRATE PROCESSING METHOD AND SUBSTRATE PROCESSING APPARATUS

(71) Applicant: Tokyo Electron Limited, Tokyo (JP)

(72) Inventors: Akihiro ISHII, Kurokawa-gun (JP); Taku GOHIRA, Kurokawa-gun (JP); Michiko NAKAYA, Nirasaki City (JP)

(73) Assignee: Tokyo Electron Limited, Tokyo (JP)

(21) Appl. No.: 19/078,654

(22) Filed: Mar. 13, 2025

Related U.S. Application Data
(63) Continuation of application No. PCT/JP2023/033435, filed on Sep. 13, 2023.

(30) Foreign Application Priority Data
Sep. 22, 2022 (JP) 2022-151342

(51) Int. Cl. H01L 21/311; H01J 37/32

(52) U.S. Cl. CPC H01L 21/31116; H01J 37/32449; H01L 21/31144; H01J 2237/332; H01J 2237/334

(57) ABSTRACT

A method of processing a substrate including an etching target film and a mask provided on the etching target film and having an opening, may include: (a) forming a first layer containing a nitrogen atom and a hydrogen atom on a side wall of a recess formed in the etching target film corresponding to the opening, using a first process gas; (b) forming a second layer from the first layer, using a second process gas containing a phosphorus-containing gas; and (c) etching the recess using a third process gas.

### CROSS-REFERENCE TO RELATED APPLICATIONS

This application is a continuation application of PCT Application No. PCT/JP2023/033435, filed on Sep. 13, 2023, which claims the benefit of priority from Japanese Patent Application No. 2022-151342, filed on Sep. 22, 2022. The entire contents of the above listed PCT and priority applications are incorporated herein by reference.

### BACKGROUND

### Field

Example embodiments of the present disclosure relate to a substrate processing method and a substrate processing apparatus.

### Description of the Related Art

Japanese Unexamined Patent Publication No. 2008-60566 discloses a method of forming a recess in a dielectric layer through etching. In this method, a mask is formed on the dielectric layer. Next, a protective silicon-containing film is formed on the mask. Next, the recess is formed through etching using the mask and the protective silicon-containing film.

### SUMMARY

In an example embodiment, a method of processing a substrate including an etching target film and a mask provided on the etching target film and having an opening, may include: (a) forming a first layer containing a nitrogen atom and a hydrogen atom on a side wall of a recess formed in the etching target film corresponding to the opening, using a first process gas; (b) forming a second layer from the first layer, using a second process gas containing a phosphorus-containing gas; and (c) etching the recess using a third process gas.

### BRIEF DESCRIPTION OF THE DRAWINGS

FIG. 1 is a schematic diagram illustrating a substrate processing apparatus according to an example embodiment.

FIG. 2 is a schematic diagram illustrating the substrate processing apparatus according to an example embodiment.

FIG. 3 is a flowchart illustrating a substrate processing method according to an example embodiment.

FIG. 4 is a partially enlarged cross-sectional view of an example substrate.

FIG. 5 is a cross-sectional view illustrating a step of the substrate processing method according to an example embodiment.

FIG. 6 is a cross-sectional view illustrating a step of the substrate processing method according to an example embodiment.

FIG. 7 is a cross-sectional view illustrating a step of the substrate processing method according to an example embodiment.

FIG. 8 is a cross-sectional view illustrating a step of the substrate processing method according to an example embodiment.

FIG. 9 is a partially enlarged cross-sectional view of an example substrate obtained by performing the substrate processing method according to an example embodiment.

### DETAILED DESCRIPTION

Hereinafter, various example embodiments will be described in detail with reference to the drawings. In the drawing, the same or equivalent portions are denoted by the same reference symbols.

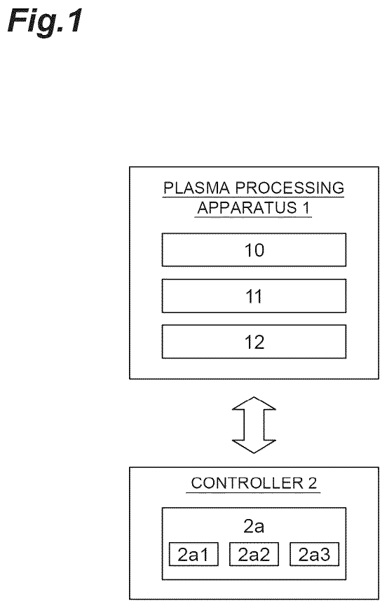

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2al, a storage 2a2, and a communication interface 2a3. The controller 2 is implemented in, for example, a computer 2a. The processor 2al may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

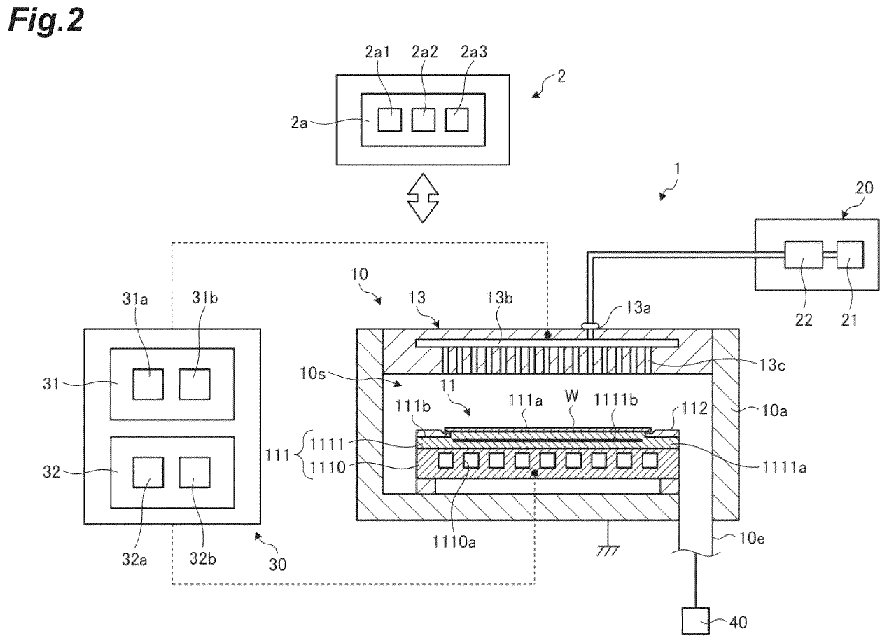

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 11a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode IIIlb may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

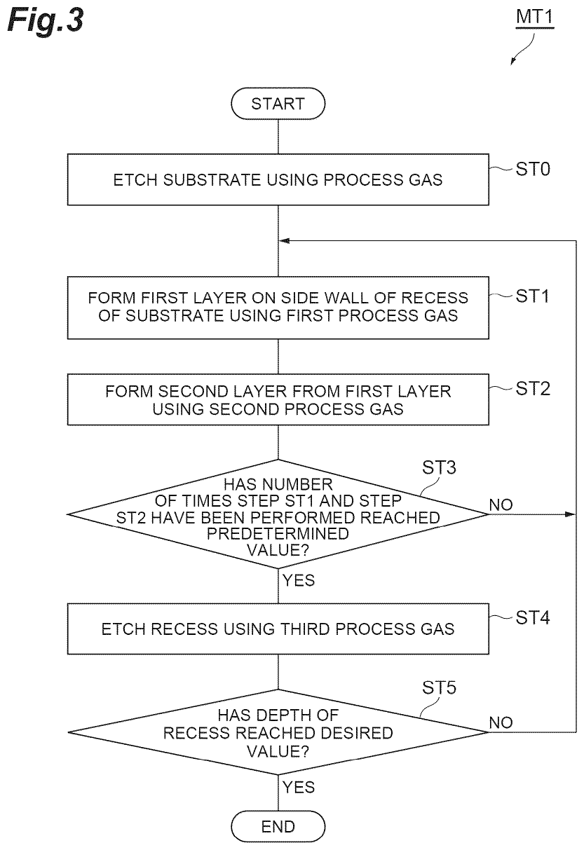

FIG. 3 is a flowchart illustrating a substrate processing method according to an example embodiment. The substrate processing method illustrated in FIG. 3 (hereinafter, referred to as “method MT1”) may be performed by a substrate processing apparatus of the above-described embodiment. The method MT1 may be applied to a substrate W.

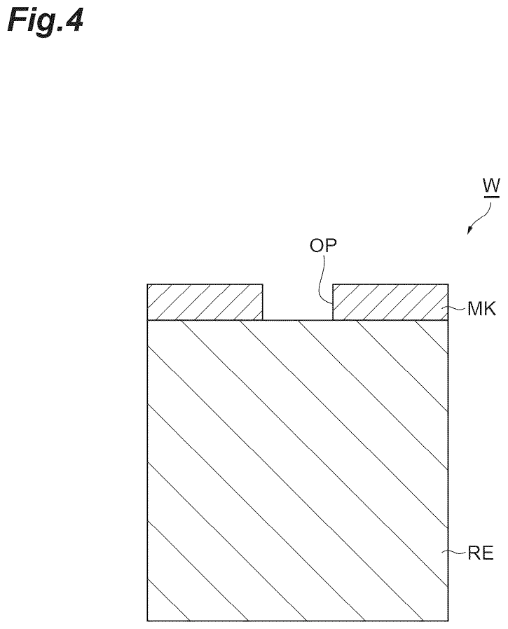

FIG. 4 is a partially enlarged cross-sectional view of an example substrate. As illustrated in FIG. 4, in an embodiment, the substrate W includes an etching target film RE and a mask MK. The mask MK is provided on the etching target film RE. The etching target film RE may be provided on an underlying region.

The etching target film RE may include a silicon-containing film. The silicon-containing film may contain nitrogen or may not contain nitrogen. The silicon-containing film may be a single layer film of any of a silicon oxide film (SiO₂ film), a silicon nitride film (SiN film), a silicon oxynitride film (SiON), a silicon carbide film (SiC film), a silicon carbonitride film (SiCN film), an organic-containing silicon oxide film (SiOCH film), and a silicon film (Si film), or may be a laminated film including at least two thereof. The silicon-containing film may be a multilayer film in which at least two types of silicon-containing films are alternately arranged. The silicon nitride film (SiN film), the silicon oxynitride film (SiON film), or the silicon carbonitride film (SiCN film) is a silicon-containing film which contains nitrogen. The silicon oxide film (SiO₂ film), the silicon carbide film (SiC film), the organic-containing silicon oxide film (SiOCH film), or the silicon film (Si film) is a silicon-containing film which contains no nitrogen. The silicon film (Si film) may be a single crystal silicon film, a polycrystalline silicon film (Poly-Si film), or an amorphous silicon film (α-Si film). The etching target film RE may include a film that contains hydrogen. The etching target film RE may be a film in which a hydrogen-containing gas is incorporated. Examples of the hydrogen-containing gas include a hydrogen gas and water vapor (H₂O). The etching target film RE may include a film containing oxygen.

The mask MK has an opening OP. The mask MK may have a plurality of openings OP. The opening OP may have a hole pattern or a line pattern. The width (Critical Dimension: CD) of the opening OP may be, for example, 100 nm or less. A distance between the adjacent openings OP may be, for example, 100 nm or less. The mask MK may include an organic film (carbon-containing film). The organic film may include at least one selected from the group consisting of a spin on carbon (SOC) film and an amorphous carbon film.

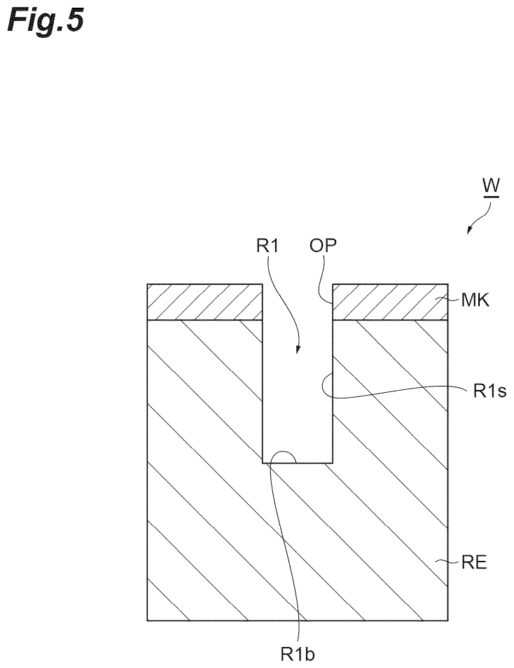

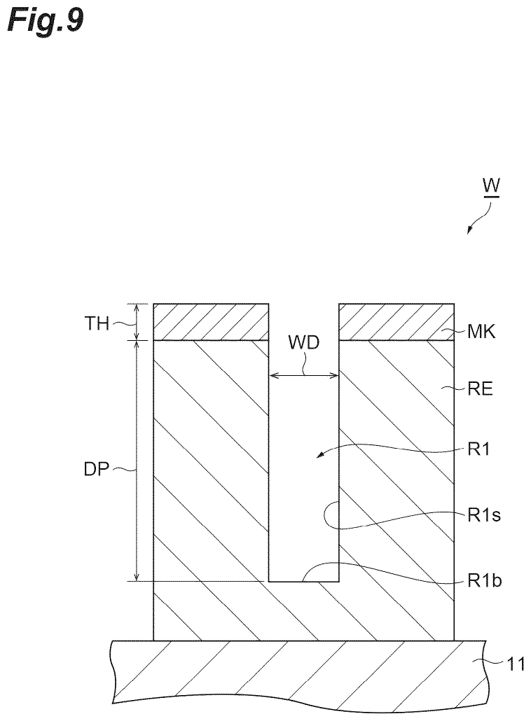

In the following, the method MT1 will be described with reference to FIGS. 3 to 9 by using, as an example, the case where the method MT1 is applied to the substrate W by using the substrate processing apparatus in the above-described embodiment. Each of FIGS. 5 to 8 is a cross-sectional view illustrating a step of the substrate processing method according to the example embodiment. FIG. 9 is a partially enlarged cross-sectional view of an example substrate obtained by performing the substrate processing method according to the example embodiment. In a case where a plasma processing apparatus 1 is used, the method MT1 may be performed in the plasma processing apparatus 1 in a manner that a controller 2 controls each unit of the plasma processing apparatus 1. In the method MT1, as illustrated in FIG. 2, the substrate W on a substrate support 11 disposed in a plasma processing chamber 10 is processed. The substrate W may be etched by means of the method MT1.

As illustrated in FIG. 3, the method MT1 may include Step ST0, Step ST1, Step ST2, Step ST3, Step ST4, and Step ST5. The method MT1 may not include Step ST0. The method MT1 may not include Step ST3. The method MT1 may not include Step ST5.

Step ST0 to Step ST5 may be executed in order. Step ST1 and Step ST0 may be simultaneously performed. At least two of Step ST1, Step ST2, and Step ST4 may be simultaneously performed. For example, Step ST4 may be performed after Step ST1 and Step ST2 are simultaneously performed. After Step ST1 is performed, Step ST2 and Step ST4 may be simultaneously performed. Step ST1, Step ST2, and Step ST4 may be simultaneously performed. After Step ST2 is performed, Step ST4 and Step ST1 may be simultaneously performed. That is, Step ST4 may be performed simultaneously with Step ST1 after Step ST4. In Step ST0 to Step ST5, the substrate W may be processed in-situ. In the following, Step ST0 to Step ST5 will be described.

### (Step ST0)

As illustrated in FIG. 5, the substrate W of FIG. 4 may be etched by using a process gas. In Step ST0, plasma generated from the process gas may be used. By the etching, a recess R1 corresponding to the opening OP of the mask MK is formed in the etching target film RE. A plurality of the recesses R1 may be formed in the etching target film RE. The recess R1 has a side wall R1s and a bottom Rib. The recess R1 may be an opening. The recess R1 is, for example, a hole or a trench. The recess R1 may be formed by plasma etching using the plasma processing apparatus 1, similar to Step ST4 which will be described later. In a case where Step ST0 is not performed, the substrate W of FIG. 5 having the recess R1 may be placed on the substrate support 11 in the plasma processing chamber 10.

### (Step ST1)

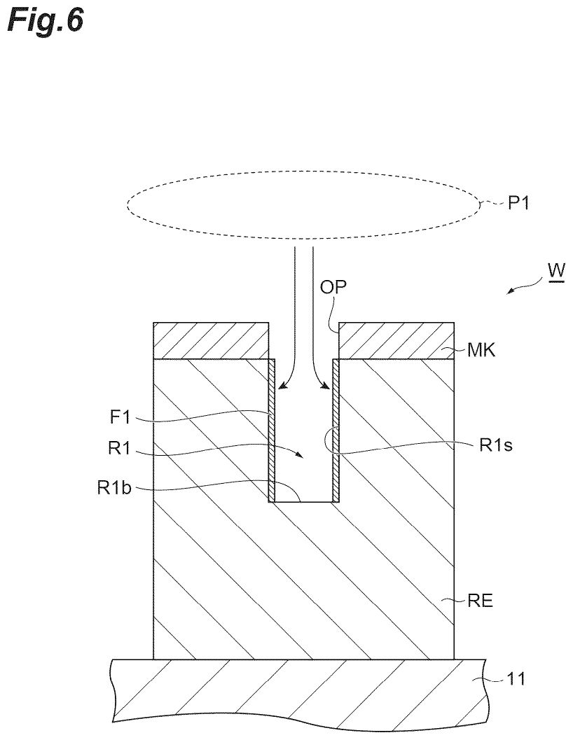

As illustrated in FIG. 6, a first layer F1 is formed on the side wall R1s of the recess R1 of the substrate W using the first process gas. In Step ST1, a first plasma P1 generated from the first process gas may be used. In Step ST1, the substrate W may be exposed to the first process gas or the first plasma P1. The first process gas or the first plasma P1 is capable of forming the first layer F1 on the side wall R1s of the recess R1 of the substrate W. The first plasma P1 may be generated by a plasma generator 12 of the plasma processing apparatus 1. The first process gas may be supplied from the gas supply 20 of the plasma processing apparatus 1 into the plasma processing chamber 10.

The first process gas may include at least one selected from the group consisting of a hydrogen atom and a nitrogen atom. The first process gas may include at least one selected from the group consisting of a hydrogen-containing gas, a nitrogen-containing gas, an oxygen-containing gas, and a fluorine-containing gas.

The hydrogen-containing gas may include at least one selected from the group consisting of an H₂ gas, an H₂O gas, a hydrocarbon gas, a hydrofluorocarbon gas, an NH₃ gas, an HF gas, and an ammonia (NH₃) gas.

The nitrogen-containing gas may include at least one selected from the group consisting of an N₂ gas, an ammonia (NH₃) gas, an NF₃ gas, an NO gas, and an NO₂ gas.

The oxygen-containing gas may include at least one selected from the group consisting of an O₂ gas, an H₂O gas, a CO gas, a CO₂ gas, an NO gas, an NO₂ gas, and an SO₂ gas.

The fluorine-containing gas may include at least one selected from the group consisting of an HF gas, a BF₃ gas, a fluorocarbon gas, a hydrofluorocarbon gas, a PF₃ gas, a PF₅ gas, an NF₃ gas, an SF₆ gas, an F₂ gas, a CIF₃ gas, an IF₇ gas, a MoF₆ gas, and a WF₆ gas. The fluorocarbon gas may include at least one selected from the group consisting of C₄F₆ gas, C₄F₈ gas, C₃F₈ gas, and CF₄ gas. The hydrofluorocarbon gas may contain at least one selected from the group consisting of a CHF₃ gas, a CH₂F₂ gas, a CH₃F gas, a C₃H₂F₄ gas, and a C₄H₂F₆ gas.

In a case where the etching target film RE contains nitrogen, the first process gas may not contain the nitrogen atom and may contain the hydrogen atom. In this case, the nitrogen atom derived from the etching target film RE and the hydrogen atom derived from the first process gas are included in the first layer F1. In a case where the etching target film RE does not contain nitrogen, the first process gas may contain a hydrogen atom and a nitrogen atom. In this case, the hydrogen atom and the nitrogen atom derived from the first process gas are included in the first layer F1. In a case where the etching target film RE includes the hydrogen atom, the first process gas may not include the hydrogen atom and may include the nitrogen atom. In this case, the first layer F1 includes the hydrogen atom derived from the etching target film RE and the nitrogen atom derived from the first process gas. In a case where the etching target film RE includes an oxygen atom, the first process gas may include the hydrogen atom and the nitrogen atom. In this case, the hydrogen atom and the nitrogen atom derived from the first process gas are included in the first layer F1.

The first layer F1 contains the nitrogen atom and the hydrogen atom. The first layer F1 may contain ammonia (NH₃) or a compound having an amino group (—NH₂). The first layer F1 is, for example, an adsorped ammonia layer. The first layer F1 is formed as a result of an interaction (for example, adsorption or a chemical reaction) between the first plasma P1 and the etching target film RE. Due to an aspect ratio of the recess R1, the first plasma P1 is less likely to reach the bottom Rib of the recess R1 than the side wall R1s of the recess R1, so that the first layer F1 is less likely to be formed on the bottom Rib of the recess R1.

Since reactivity of ammonia (NH₃) gas is high, in a case where the first process gas contains ammonia (NH₃) gas, it is not necessary to generate the first plasma P1. Even in this case, it is expected that the first layer F1 containing ammonia (NH₃) or a compound having an amino group (—NH₂) is formed on the side wall R1s of the recess R1 of the substrate W.

In Step ST1, a temperature of the substrate W may be 60° C. or lower, 55° C. or lower, or 30° C. or lower. In this case, a temperature of the substrate support 11 for supporting the substrate W may be 60° C. or lower, 30° C. or lower, 0° C. or lower, −30° C. or lower, or −70° C. or lower. In one example, the temperature of the substrate support 11 for supporting the substrate W may be −30° C. or higher and 0° C. or lower.

In Step ST1, the recess R1 may be etched. In this case, since the bottom R1b of the recess R1 is etched, the first layer F1 is less likely to be formed on the bottom Rib of the recess R1.

### (Step ST2)

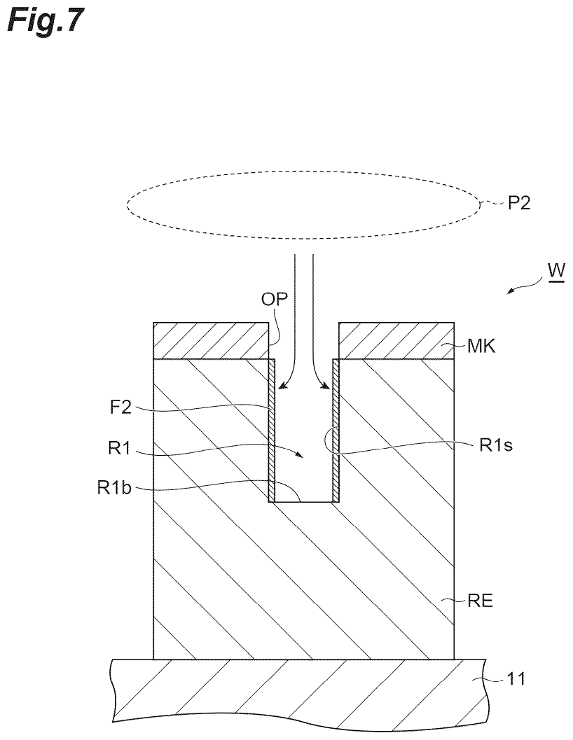

As illustrated in FIG. 7, the second layer F2 is formed from the first layer F1 using the second process gas. The second process gas may be the same as the first process gas or may be different from the first process gas. In Step ST2, a second plasma P2 generated from the second process gas may be used. In Step ST2, the substrate W may be exposed to the second process gas or the second plasma P2. The second process gas or the second plasma P2 is capable of forming the second layer F2 from the first layer F1. The second plasma P2 may be generated by the plasma generator 12 of the plasma processing apparatus 1. The second process gas may be supplied from the gas supply 20 of the plasma processing apparatus 1 into the plasma processing chamber 10.

The second process gas includes a phosphorus-containing gas. The phosphorus-containing gas may contain a halogen. The phosphorus-containing gas may contain at least one selected from the group consisting of phosphorus hydride, phosphorus fluoride, phosphor halide other than fluoride, and phosphoryl halide. The phosphorus-containing gas may contain at least one selected from the group consisting of PH₃, PF₃, PF₅, PCl₃, PBr₃, POF₃, POCl₃, and POBr₃.

The second process gas may further include at least one selected from the group consisting of a halogen-containing gas, an oxygen-containing gas, and a hydrogen-containing gas. The halogen-containing gas may be a fluorine-containing gas. The halogen-containing gas may contain a halogen compound having a polarity. The halogen compound may be a hydrogen halide (HX: X is any one of F, Cl, Br, and I) or may be an alkyl halide (CₙH₂ₙ₊₁X: X is any one of F, Cl, Br, and I, and n is an integer of 1 or more). The alkyl halide is, for example, CH₃Br (bromomethane) or C₂H₅Cl (chloroethane). The second process gas may not contain a fluorocarbon gas. Examples of the oxygen-containing gas, the hydrogen-containing gas, and the fluorine-containing gas, which may be included in the second process gas, are the same as the examples of the oxygen-containing gas, the hydrogen-containing gas, and the fluorine-containing gas, which may be included in the first process gas.

The second layer F2 may contain at least one selected from the group consisting of ammonium hexafluorophosphate (NH₄PF₆), ammonium phosphate ((NH₄)₃PO₄), diammonium hydrogen phosphate ((NH₄)₂HPO₄), and ammonium dihydrogen phosphate (NH₄H₂PO₄). The second layer F2 may be formed by reacting the phosphorus-containing gas with the first layer F1. The second layer F2 may function as a protective layer against etching in Step ST4 which will be described later. Since the second layer F2 is formed from the first layer F1, it is less likely to be formed on the bottom Rib of the recess R1. The second layer F2 may further contain ammonium halide (NH₄X: X is any one of F, Cl, Br, and I) or amine halide (NH₂X: X is any one of F, Cl, Br, and I).

In Step ST2, an example of the temperature of the substrate W may be the same as an example of the temperature of the substrate W in Step ST1. In this case, an example of the temperature of the substrate support 11 for supporting the substrate W may be the same as the example of the temperature of the substrate W in Step ST1.

After Step ST2, a purge in the plasma processing chamber 10 may be performed. A purge gas may be supplied from the gas supply 20 of the plasma processing apparatus 1 into the plasma processing chamber 10.

### (Step ST3)

As illustrated in FIG. 3, Step ST1 and Step ST2 may be repeated. In Step ST3, it may be determined whether the number of times Step ST1 and Step ST2 have been performed has reached a predetermined value. The determination may be performed by the controller 2 of the substrate processing apparatus. In a case where the number of times Step ST1 and Step ST2 have been performed has not reached the predetermined value, the process returns to Step ST1, and Step ST1 and Step ST2 are repeated. In a case where the number of times Step ST1 and Step ST2 have been performed has reached the predetermined value, Step ST3 is ended, and Step ST4 is performed. In this way, the method MT1 may further include a step of repeating Step ST1 and Step ST2 before Step ST4.

### (Step ST4)

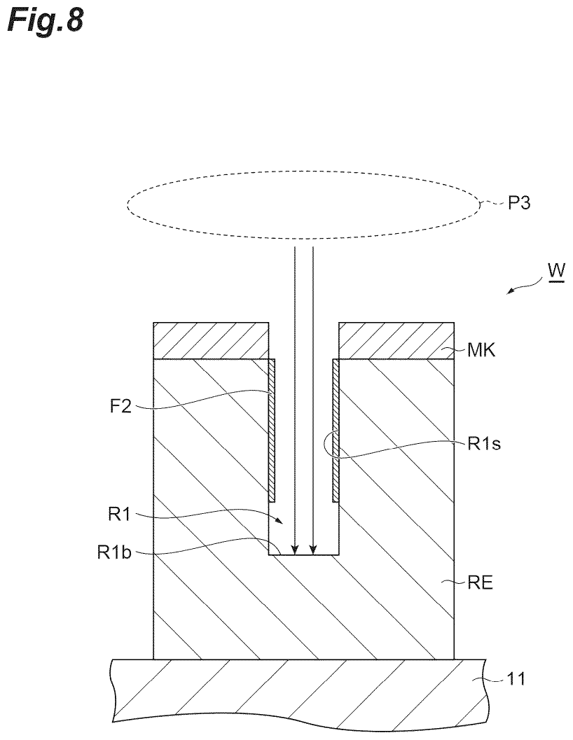

As illustrated in FIG. 8, the recess R1 is etched using the third process gas. In Step ST4, the bottom Rib of the recess R1 may be etched. The third process gas may be the same as the first process gas or may be different from the first process gas. The third process gas may be the same as the second process gas or may be different from the second process gas. In Step ST4, the third plasma P3 generated from the third process gas may be used. In Step ST4, the substrate W may be exposed to the third process gas or the third plasma P3. The third process gas or the third plasma P3 is capable of etching the recess R1. The third plasma P3 may be generated by the plasma generator 12 of the plasma processing apparatus 1. The third process gas may be supplied from the gas supply 20 of the plasma processing apparatus 1 into the plasma processing chamber 10.

In Step ST4, an example of the temperature of the substrate W may be the same as an example of the temperature of the substrate W in Step ST1. In this case, an example of the temperature of the substrate support 11 for supporting the substrate W may be the same as the example of the temperature of the substrate W in Step ST1.

In Step ST4, a bias power may be applied to the substrate support 11 for supporting the substrate W. The bias power may be applied by the power supply 30 of FIG. 2. An etching rate of the bottom Rib of the recess R1 is increased by the bias power.

### (Step ST5)

As illustrated in FIG. 3, Step ST1 to Step ST4 may be repeated. In Step ST5, as illustrated in FIG. 9, it may be determined whether a depth DP of the recess R1 has reached a threshold value. The depth DP of the recess R1 may be monitored by, for example, an end point monitor. The determination may be performed by the controller 2 of the substrate processing apparatus. In a case where the depth DP of the recess R1 has reached the threshold value, the method MT1 is ended. In a case where the depth DP of the recess R1 has not reached the threshold value, the process returns to Step ST1, and the Step ST1 to Step ST4 are repeated. In Step ST5, it may be determined whether the number of repetitions of Step ST1 to Step ST4 has reached a threshold value. In this way, the method MT1 may further include a step of repeating Step ST1, Step ST2, and Step ST4 after Step ST4.

In a case where Step ST4 is performed simultaneously with Step ST1 after Step ST4, the third plasma P3 also serves as the first plasma P1. As a result, the etching of the recess R1 and the formation of the first layer F1 are simultaneously performed.

After the end of the method MT1, the depth DP of the recess R1 may be 3 μm or more, and the aspect ratio of the recess R1 (depth DP with respect to a width WD of the recess R1) may be 30 or more. After the end of the method MT1, a ratio (TH/DP) of a thickness TH of the mask MK to the depth DP of the recess R1 may be ⅕ or more.

According to the method MT1 of the above-described embodiment, in Step ST4, since the second layer F2 is formed on the side wall R1s of the recess R1, the etching of the side wall R1s of the recess R1 is suppressed. Therefore, it is possible to suppress the shape defect (bowing) of the side wall R1s of the recess R1 in the etching.

The second layer F2 formed on the side wall R1s of the recess R1 suppresses the etching of the side wall R1s of the recess R1, and the bottom R1b of the recess R1 is etched. However, the etching is not limited to the bottom R1b of the recess R1. For example, as illustrated in FIG. 8, by etching the bottom R1b of the recess R1, the side wall R1s of the recess R1 on which the second layer F2 is not formed is newly exposed, and the exposed side wall R1s of the recess R1 may be etched. In addition, in a case where the aspect ratio of the recess R1 is high, the second layer F2 may be formed in an upper region of the side wall R1s of the recess R1, which is a portion where the shape defect (bowing) is likely to occur, and may not be formed in a lower region thereof. In such a case, not only the bottom R1b of the recess R1 may be etched, but also the side wall R1s of the recess R1 on which the second layer F2 is not formed may be etched. In a case where the aspect ratio of the recess R1 is high, the recess R1 tends to have a tapered shape in which the width of the recess R1 decreases from an upper end of the recess R1 toward the bottom R1b. However, by etching the side wall R1s of the recess R1 on which the second layer F2 is not formed, the width of the recess R1 in the bottom R1b may be widened.

According to the method MT1, closing of the opening OP of the mask MK through the first layer F1 and the second layer F2 is suppressed.

Although the various example embodiments have been described above, various additions, omissions, substitutions, and changes may be made without being limited to the example embodiments described above. Other embodiments may be formed by combining elements in different embodiments.

Various experiments performed for evaluating the method MT1 are described below. The experiments described below do not limit the present disclosure.

### First Experiment

In the first experiment, a substrate W including a laminated film in which a silicon nitride film and a silicon oxide film were alternately laminated and a mask MK on the laminated film was prepared. Thereafter, the method MT1 was executed on the substrate W using the above-described plasma processing system. Step ST1, Step ST2, and Step ST4 were simultaneously performed. Step ST0, Step ST3, and Step ST5 were not performed. In Step ST1, Step ST2, and Step ST4, plasma generated from a process gas including a hydrogen-containing gas and a PF₃ gas was used. In Step ST1, Step ST2, and Step ST4, a temperature of the substrate W was 30° C.

### Experimental Results

The components of the side wall of the recess R1 of the substrate W on which the method MT1 was executed in the first experiment were analyzed by time-of-flight secondary ion mass spectrometry (TOF-SIMS). As a result, ammonium hexafluorophosphate and phosphate were detected.

Here, the various example embodiments included in the present disclosure are described in [E1] to [E23] below.

[E1] A method of processing a substrate including an etching target film and a mask provided on the etching target film and having an opening, the method comprising:
(a) forming a first layer containing a nitrogen atom and a hydrogen atom on a side wall of a recess formed in the etching target film corresponding to the opening, using a first process gas;
(b) forming a second layer from the first layer, using a second process gas containing a phosphorus-containing gas; and
(c) etching the recess using a third process gas.

According to the method [E1], in (c), since the second layer is formed on the side wall of the recess, the etching of the side wall of the recess is suppressed. Therefore, it is possible to suppress the shape defect of the side wall of the recess in the etching.

[E2] The method according to [E1],
wherein in the (a), a first plasma generated from the first process gas is used,
in the (b), a second plasma generated from the second process gas is used, and
in the (c), a third plasma generated from the third process gas is used.

[E3] The method according to [E1] or [E2], further comprising: repeating the (a) and the (b) before the (c).

[E4] The method according to any one of [E1] to [E3], further comprising:
after the (c), repeating the (a), the (b), and the (c).

In this case, it is possible to form a deep recess.

[E5] The method according to [E4],
wherein the repeated (a) is performed simultaneously with the (c).

In this case, it is possible to form the first layer on the side wall of the recess while etching the recess.

[E6] The method according to any one of [E1] to [E5],
wherein the (b) is performed after the (a), and
the (c) is performed after the (b).

[E7] The method according to [E1] or [E2],
wherein the (c) is performed after the (a) and the (b) are performed simultaneously.

[E8] The method according to [E1] or [E2],
wherein the (b) and the (c) are performed simultaneously after the (a) is performed.

[E9] The method according to [E1] or [E2],
wherein the (a), the (b), and the (c) are performed simultaneously.

[E10] The method according to any one of [E1] to [E9],
wherein the etching target film includes a silicon-containing film.

[E11] The method according to [E10],
wherein the silicon-containing film contains nitrogen, and
the first process gas contains the hydrogen atom.

[E12] The method according to [E10],
wherein the silicon-containing film does not contain nitrogen, and
the first process gas contains the hydrogen atom and the nitrogen atom.

[E13] The method according to any one of [E1] to [E12],
wherein the etching target film includes a film containing hydrogen, and
the first process gas contains the nitrogen atom.

[E14] The method according to any one of [E1] to [E13],
wherein the etching target film includes a film containing oxygen, and
the first process gas contains the hydrogen atom and the nitrogen atom.

[E15] The method according to any one of [E1] to [E14],
wherein the second process gas further contains a halogen-containing gas.

[E16] The method according to [E15],
wherein the halogen-containing gas contains a halogen compound having a polarity.

In this case, the reactivity of the halogen-containing gas with the first layer is increased.

[E17] The method according to any one of [E1] to [E16],
wherein the phosphorus-containing gas includes at least one selected from the group consisting of PH₃, PF₃, PF₅, PCl₃, PBr₃, POF₃, POCl₃, and POBr₃.

[E18] The method according to any one of [E1] to [E17],
wherein the first layer includes ammonia or a compound having an amino group.

[E19] The method according to any one of [E1] to [E18],
wherein the second layer includes at least one selected from the group consisting of ammonium hexafluorophosphate, ammonium phosphate, diammonium hydrogen phosphate, and ammonium dihydrogen phosphate.

[E20] The method according to any one of [E1] to [E19],
wherein, in the (c), a bias power is applied to a substrate support for supporting the substrate.

In this case, it is possible to selectively etch the recess.

[E21] The method according to any one of [E1] to [E20],
wherein in the (b), a temperature of the substrate is 60° C. or lower.

[E22] A substrate processing apparatus comprising:
a chamber;
a substrate support for supporting a substrate in the chamber, the substrate including an etching target film and a mask provided on the etching target film and having an opening;
a gas supply configured to supply a first process gas, a second process gas, and a third process gas into the chamber, the second process gas including a phosphorus-containing gas; and
a controller,
wherein the controller is configured to control the gas supply to
(a) form a first layer containing a nitrogen atom and a hydrogen atom on a side wall of a recess formed in the etching target film corresponding to the opening, using the first process gas,
(b) form a second layer from the first layer, using the second process gas, and
(c) etch the recess using the third process gas.

[E23] A method of processing a substrate including an etching target film and a mask provided on the etching target film and having an opening, the method comprising:
(a) exposing the substrate to a first process gas, wherein the first process gas is capable of forming a first layer containing a nitrogen atom and a hydrogen atom on a side wall of a recess formed in the etching target film corresponding to the opening;
(b) exposing the substrate to a second process gas containing a phosphorus-containing gas, wherein the second process gas is capable of forming a second layer from the first layer; and
(c) exposing the substrate to a third process gas, wherein the third process gas is capable of etching the recess.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of processing a substrate including an etching target film and a mask provided on the etching target film and having an opening, the method comprising:
(a) forming a first layer containing a nitrogen atom and a hydrogen atom on a side wall of a recess formed in the etching target film corresponding to the opening, using a first process gas;
(b) forming a second layer from the first layer, using a second process gas containing a phosphorus-containing gas; and
(c) etching the recess using a third process gas.

2. The method according to claim 1,
wherein in the (a), a first plasma generated from the first process gas is used,
in the (b), a second plasma generated from the second process gas is used, and
in the (c), a third plasma generated from the third process gas is used.

3. The method according to claim 1, further comprising:
repeating the (a) and the (b) before the (c).

4. The method according to claim 1, further comprising:
after the (c), repeating the (a), the (b), and the (c).

5. The method according to claim 4,
wherein the repeated (a) is performed simultaneously with the (c).

6. The method according to claim 1,
wherein the (b) is performed after the (a), and
the (c) is performed after the (b).

7. The method according to claim 1,
wherein the (a), the (b), and the (c) are performed simultaneously.

8. The method according to claim 1,
wherein the etching target film includes a silicon-containing film.

9. The method according to claim 8,
wherein the silicon-containing film contains nitrogen, and
the first process gas contains the hydrogen atom.

10. The method according to claim 8,
wherein the silicon-containing film does not contain nitrogen, and
the first process gas contains the hydrogen atom and the nitrogen atom.

11. The method according to claim 1,
wherein the etching target film includes a film containing hydrogen, and
the first process gas contains the nitrogen atom.

12. The method according to claim 1,
wherein the etching target film includes a film containing oxygen, and
the first process gas contains the hydrogen atom and the nitrogen atom.

13. The method according to claim 1,
wherein the second process gas further contains a halogen-containing gas.

14. The method according to claim 13,
wherein the halogen-containing gas contains a halogen compound having a polarity.

15. The method according to claim 1,
wherein the phosphorus-containing gas includes at least one selected from the group consisting of PH₃, PF₃, PF₅, PCl₃, PBr₃, POF₃, POCl₃, and POBr₃.

16. The method according to claim 1,
wherein the first layer includes ammonia or a compound having an amino group.

17. The method according to claim 1,
wherein the second layer includes at least one selected from the group consisting of ammonium hexafluorophosphate, ammonium phosphate, diammonium hydrogen phosphate, and ammonium dihydrogen phosphate.

18. The method according to claim 1,
wherein, in the (c), a bias power is applied to a substrate support for supporting the substrate.

19. The method according to claim 1,
wherein in the (b), a temperature of the substrate is 60° C. or lower.

20. A substrate processing apparatus comprising:
a chamber;
a substrate support for supporting a substrate in the chamber, the substrate including an etching target film and a mask provided on the etching target film and having an opening;
a gas supply configured to supply a first process gas, a second process gas, and a third process gas into the chamber, the second process gas including a phosphorus-containing gas; and
a controller,
wherein the controller is configured to control the gas supply to
(a) form a first layer containing a nitrogen atom and a hydrogen atom on a side wall of a recess formed in the etching target film corresponding to the opening, using the first process gas,
(b) form a second layer from the first layer, using the second process gas, and
(c) etch the recess using the third process gas.

21. A method of processing a substrate including an etching target film and a mask provided on the etching target film and having an opening, the method comprising:
(a) exposing the substrate to a first process gas, wherein the first process gas is capable of forming a first layer containing a nitrogen atom and a hydrogen atom on a side wall of a recess formed in the etching target film corresponding to the opening;
(b) exposing the substrate to a second process gas containing a phosphorus-containing gas, wherein the second process gas is capable of forming a second layer from the first layer; and
(c) exposing the substrate to a third process gas, wherein the third process gas is capable of etching the recess.
